(19) United States
(12) Patent Application Publication
(10) Pub. No.: US 2026/0076109 A1
(43) Pub. Date: Mar. 12, 2026

(54) DOPED MULTI-LAYER STRUCTURES FOR STACK UNIFORMITY IN DEVICES, AND RELATED METHODS AND APPARATUS

(71) Applicant: Applied Materials, Inc., Santa Clara, CA (US)

(72) Inventors: Mahendra PAKALA, Santa Clara, CA (US); Roya BAGHI, Santa Clara, CA (US); Xin MENG, Santa Clara, CA (US); Sangwook KIM, Palo Alto, CA (US)

(21) Appl. No.: 19/323,116

(22) Filed: Sep. 9, 2025

Related U.S. Application Data
(60) Provisional application No. 63/692,550, filed on Sep. 9, 2024.

(51) Int. Cl. H01L 21/02; H10D 62/60; H10D 62/832

(52) U.S. Cl. CPC H10P 14/3438; H10D 62/60; H10D 62/832; H10P 14/3411

(57) ABSTRACT

Embodiments of the present disclosure generally relate to epitaxial processes and materials, and more specifically, epitaxial processes for preparing materials, layers, stacks, and devices. In one or more embodiments, a device includes a multi-layer structure disposed on a substrate. The multi-layer structure includes a plurality of doped silicon-germanium (SiGe) layers. The doped SiGe layers respectively include a dopant having a concentration in a range from about 0.01 atomic percent (at%) to about 5 at%. The multi-layer structure includes a plurality of silicon layers disposed in an alternating arrangement with the doped SiGe layers such that a respective silicon layer is disposed between a respective first doped SiGe layer and a respective second doped SiGe layer.

### CROSS-REFERENCE TO RELATED APPLICATIONS

This application claims the benefit of United States provisional patent application serial number 63/692,550, filed September 9, 2024, which is herein incorporated by reference in its entirety.

### BACKGROUND

### Field

Embodiments of the present technology relates to semiconductor systems and processes. More specifically, the present technology relates to three-dimensional (3D) dynamic random-access memory (DRAM) devices (3D DRAM), and methods of forming such devices.

### Description of the Related Art

Three-dimensional (3D) dynamic random-access memory (DRAM) devices pose challenges in manufacturability due to their three-dimensional (3D) designs and small sizes. Although vertical stacking individual memory cells improve density and performance of the memory devices, achieving ultra-fine features and deep vertical structures with tight pitch pose challenges to current fabrication methods. For example, the deep vertical structures can exacerbate issues with non-uniformities (such as structural non-uniformities and/or performance non-uniformities).

Thus, there is a need for systems and methods that can fabricate a 3D DRAM device while ensuring pattern fidelity and device performance across the layers.

### SUMMARY

Embodiments of the present disclosure generally relate to epitaxial processes and materials, and more specifically, epitaxial processes for preparing materials, layers, stacks, and devices.

In one or more embodiments, a device includes a multi-layer structure disposed on a substrate. The multi-layer structure includes a plurality of doped silicon-germanium (SiGe) layers. The doped SiGe layers respectively include a dopant having a concentration in a range from about 0.01 atomic percent (at%) to about 5 at%. The multi-layer structure includes a plurality of silicon layers disposed in an alternating arrangement with the doped SiGe layers such that a respective silicon layer is disposed between a respective first doped SiGe layer and a respective second doped SiGe layer.

In one or more embodiments, a method of processing a substrate includes flowing a first gas and a dopant precursor to form a doped SiGe layer. The doped SiGe layer including a dopant in a range from about 0.1 at% to about 3 at%. The method includes ceasing the flow of the dopant precursor; and flowing a second gas to form a silicon layer on the doped SiGe layer. The silicon layer and the doped SiGe layer form at least part of a multi-layer structure.

In one or more embodiments, a non-transitory computer readable medium includes instructions that when executed cause a plurality of operations to be conducted. The plurality of operations include flowing a first gas and a dopant precursor to form a doped SiGe layer, and flowing a second gas to form a silicon layer on the doped SiGe layer. The plurality of operations also include flowing an etch gas using an etch temperature that is within a range of 35 degrees Celsius to 105 degrees Celsius.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic top-view diagram of an example of a multi-chamber processing system 100, according to one or more embodiments.

FIG. 2 is a flowchart depicting a process or method 200 of processing a substrate (such as to fabricate a device), according to one or more embodiments.

FIG. 3 is a cross-sectional view of a multi-layer structure 300 of a device, according to one or more embodiments.

FIG. 4 is a cross-sectional view of a device 400, according to one or more embodiments.

FIG. 5 is a schematic side cross-sectional view of a processing chamber 500, according to one or more embodiments.

To facilitate understanding, identical reference numerals have been used, where possible, to designate identical elements that are common to the Figures. It is contemplated that elements and features of one or more embodiments may be beneficially incorporated in other embodiments.

### DETAILED DESCRIPTION

Embodiments of the present disclosure generally relate to epitaxial processes and materials, and more specifically, epitaxial processes for preparing materials, layers, stacks, and devices.

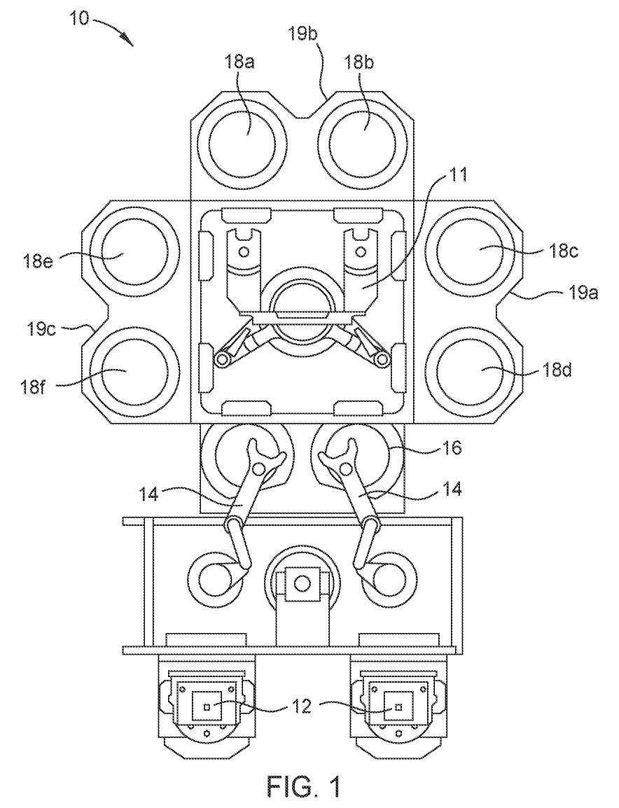

FIG. 1 is a schematic top-view diagram of an example of a multi-chamber processing system 100, according to one or more embodiments. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, wafers in the processing system 100 can be processed in and transferred between the various chambers without exposing the wafers to an ambient environment exterior to the processing system 100 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 100. Accordingly, the processing system 100 may provide for an integrated solution for some processing of wafers.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 140 and factory interface robots 142 to facilitate transfer of wafers. The docking station 140 is configured to accept one or more front opening unified pods (FOUPs) 144. In some examples, each factory interface robot 142 generally comprises a blade 148 disposed on one end of the respective factory interface robot 142 configured to transfer the wafers from the factory interface 102 to the load lock chambers 104, 106.

The load lock chambers 104, 106 have respective ports 150, 152 coupled to the factory interface 102 and respective ports 154, 156 coupled to the transfer chamber 108. The transfer chamber 108 further has respective ports 158, 160 coupled to the holding chambers 116, 118 and respective ports 162, 164 coupled to processing chambers 120, 122. Similarly, the transfer chamber 110 has respective ports 166, 168 coupled to the holding chambers 116, 118 and respective ports 170, 172, 174, 176 coupled to processing chambers 124, 126, 128, 130. The ports 154, 156, 158, 160, 162, 164, 166, 168, 170, 172, 174, 176 can be, for example, slit valve openings with slit valves for passing wafers therethrough by the transfer robots 112, 114 and for providing a seal between respective chambers to prevent a gas from passing between the respective chambers. Generally, any port is open for transferring a wafer therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 142 transfers a wafer from a FOUP 144 through a port 150 or 152 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the wafer between, for example, the atmospheric environment of the factory interface 102 and the low pressure or vacuum environment of the transfer chamber 108.

With the wafer in the load lock chamber 104 or 106 that has been pumped down, the transfer robot 112 transfers the wafer from the load lock chamber 104 or 106 into the transfer chamber 108 through the port 154 or 156. The transfer robot 112 is then capable of transferring the wafer to and/or between any of the processing chambers 120, 122 through the respective ports 162, 164 for processing and the holding chambers 116, 118 through the respective ports 158, 160 for holding to await further transfer. Similarly, the transfer robot 114 is capable of accessing the wafer in the holding chamber 116 or 118 through the port 166 or 168 and is capable of transferring the wafer to and/or between any of the processing chambers 124, 126, 128, 130 through the respective ports 170, 172, 174, 176 for processing and the holding chambers 116, 118 through the respective ports 166, 168 for holding to await further transfer. The transfer and holding of the wafer within and among the various chambers can be in the low pressure or vacuum environment provided by the gas and pressure control system.

The processing chambers 120, 122, 124, 126, 128, 130 can be any appropriate chamber for processing a wafer. In some examples, the processing chamber 122 can be capable of performing a cleaning process, the processing chamber 120 can be capable of performing an etch process, and the processing chambers 124, 126, 128, 130 can be capable of performing respective epitaxial growth processes.

A system controller 190 is coupled to the processing system 100 for controlling the processing system 100 or components thereof. For example, the system controller 190 may control the operation of the processing system 100 using a direct control of the chambers 104, 106, 108, 116, 118, 110, 120, 122, 124, 126, 128, 130 of the processing system 100 or by controlling controllers associated with the chambers 104, 106, 108, 116, 118, 110, 120, 122, 124, 126, 128, 130. In operation, the system controller 190 enables data collection and feedback from the respective chambers to coordinate performance of the processing system 100.

The system controller 190 generally includes a central processing unit (CPU) 192, memory 194, and support circuits 196. The CPU 192 may be one of any form of a general purpose processor that can be used in an industrial setting. The memory 194, or non-transitory computer-readable medium, is accessible by the CPU 192 and may be one or more of memory such as random access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, for example, a software routine. When the computer instruction code is executed by the CPU 192, the CPU 192 controls the chambers to perform processes in accordance with the various methods (such as the method 200).

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

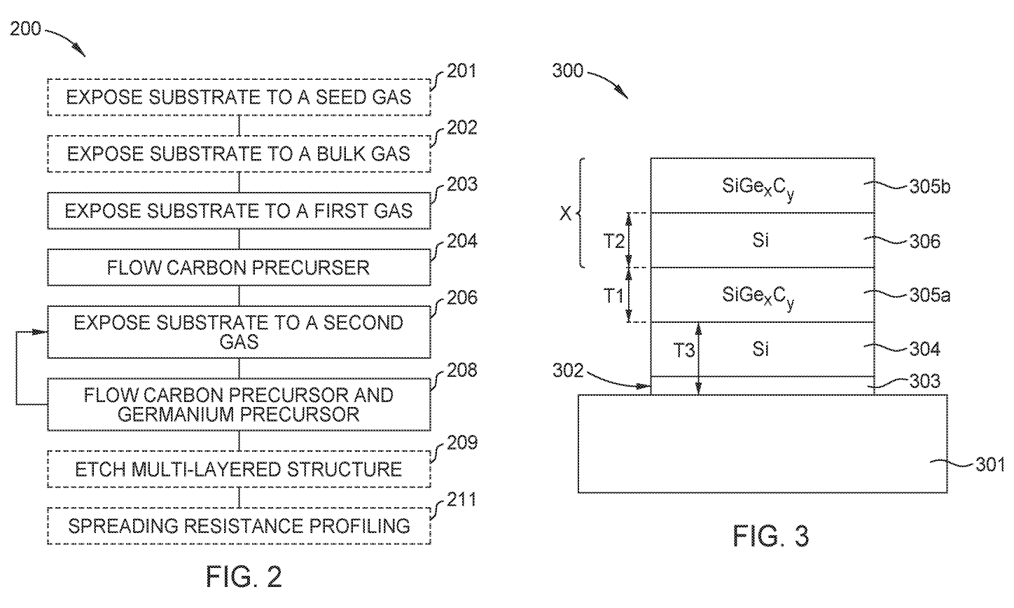

FIG. 2 is a flowchart depicting a process or method 200 of processing a substrate (such as to fabricate a device), according to one or more embodiments. The device includes a multi-layer structure, such as a multi-layered epitaxial stack. Other multi-layered epitaxial stacks and various film stacks can be deposited, fabricated, or otherwise produced by the method 200.

In one or more embodiments, the method 200 includes sequentially depositing a carbon-doped silicon-germanium layer and a silicon layer to form a mini-stack disposed on a substrate during a deposition cycle. The method 200 includes repeating the deposition cycle to form a multi-layered stack containing two or more of the carbon-doped silicon-germanium and silicon mini-stacks on the substrate.

At optional operation 201 of the method 200, the deposition cycle includes exposing the substrate to a seed gas containing the silicon precursor, the silicon-chlorine precursor, and the carrier gas described in operation 203. The seed gas can deposit a silicon seed layer on the substrate.

At optional operation 202 of the method 200, the deposition cycle includes exposing the substrate to a bulk gas containing the silicon precursor and the carrier gas described in operation 203. The bulk gas can deposit a silicon bulk layer on the silicon seed layer. Operation 202 can include ceasing the flow of the silicon-chlorin precursor used in operation 201. The silicon seed layer and the silicon bulk layer can make up a silicon film between the substrate and the multi-layer structure that includes silicon germanium layers alternating with silicon layers.

At operation 203 of the method 200, the deposition cycle includes exposing the device containing the substrate to a first gas. The first gas includes a silicon precursor, a silicon-chlorine precursor, a germanium precursor, and a carrier gas to deposit a first silicon-germanium (SiGe) layer. The silicon precursor can be or contain one or more of silane, disilane, trisilane, tetrasilane, or any combination thereof. The silicon-chlorine precursor can be or contain one or more of monochlorosilane, dichlorosilane, trichlorosilane, tetracholorosilane, hexachlorodisilane, or any combination thereof. The germanium precursor can be or contain one or more of germane, tetrachlorogermane, one or more organogermane compounds, or any combination thereof. The carrier gas can be or contain on or more of hydrogen (H2), nitrogen (N2), argon, helium, or any combination thereof. In one or more embodiments, the carrier gas contains a mixture of hydrogen and nitrogen. The mixture of hydrogen and nitrogen can have a hydrogen to nitrogen molar ratio in a range from about 1:10 to about 10:1, about 1:5 to about 5:1, about 1:3 to about 3:1, about 1:2 to about 2:1, or about 1:1.

At operation 204 of the method 200, the deposition cycle includes flowing one or more carbon precursors. The carbon precursor(s) can include one or more silicon-carbon precursors. The flow of the carbon precursor(s) can start at operation 204, and the flows of the precursors and gases in operation 203 can continue in operation 204. The flow of the carbon precursor(s) can dope the first SiGe layer with carbon. In one or more embodiments, the silicon-carbon precursor can be or contain one or more alkylsilanes. In one or more embodiments, the silicon-carbon precursor can be or contain methylsilane, dimethylsilane, or any combination thereof. The silicon-carbon precursor typically has silicon-carbon bonds which provides carbon to be incorporated into the carbon-silicon-germanium layers.

The present disclosure contemplates that the flow of the carbon precursor(s) in operation 204 can co-flow with the precursors of operation 203, can flow sequentially with the precursors of operation 203, or can flow partially sequentially with the precursors of operation 203.

Operation 206 includes exposing the substrate to a second gas. Operation 206 can include ceasing the flow of the one or more carbon precursors and the germanium precursor. In one or more embodiments, the second gas includes the silicon precursor, the silicon-chlorine precursor, and the carrier gas to deposit a silicon layer on the first SiGe layer that is doped.

At operation 208 of the method 200, the deposition cycle includes flowing the one or more carbon precursors and the germanium precursor. Operation 208 can include continuing to flow the silicon precursor, the silicon-chlorine precursor, and the carrier gas to deposit a second SiGe layer on the first SiGe layer. The second SiGe layer is doped with carbon.

Some or all of operations 201-208 can be repeated as many times as desired for forming the multi-layer structure to contain the desired number of the carbon-doped SiGe and silicon layers in an alternating arrangement on the substrate. In one or more embodiments, operation 206 and operation 208 are repeated. The operations are repeated in a range from about 1, 2, 3, 4, 5, 6, 8, 10, about 12, about 15, about 20, about 25, about 30, about 40, or about 50 times to about 60, about 70, about 80, about 90, about 100, about 120, about 140, about 150, about 160, about 180, about 200, about 250, or more times to prepare the multi-layer structure 300. For example, the deposition cycle can be repeated from about 2 times to about 250 times, about 5 times to about 200 times, about 10 times to about 200 times, about 20 times to about 200 times, about 30 times to about 200 times, about 40 times to about 200 times, about 50 times to about 200 times, about 80 times to about 200 times, about 100 times to about 200 times, about 120 times to about 200 times, about 150 times to about 200 times, about 180 times to about 200 times, about 5 times to about 100 times, about 10 times to about 100 times, about 20 times to about 100 times, about 30 times to about 100 times, about 40 times to about 100 times, about 50 times to about 100 times, about 60 times to about 100 times, about 80 times to about 100 times, or about 90 times to about 100 times to form the multi-layer structure.

In one or more embodiments, some or all of the operations 201-208 can be repeated from about 10 times to about 200 times to prepare the multi-layer structure. In one or more embodiments, some or all of the operations 201-208 can be repeated from about 30 times to about 100 times to prepare the multi-layer structure. In one or more embodiments, some or all of the operations 201-208 can be repeated from about 40 times to about 80 times to prepare the multi-layer structure.

Optional operation 209 of the method 200 includes etching the multi-layer structure. A dry etching or wet etching can be used. The etching can use an etching material that can include, for example, hydrogen fluoride (HF), ammonia (NH₃), chlorine gas (Cl₂), nitrogen trifluoride (NF₃), chlorine trifluoride (ClF₃), and/or hydrogen chloride (HCl). The etching can clean the multi-layer structure, such as by removing an oxide from the multi-layer structure, and/or the etching can form trenches in the multi-layer structure. The etching is conducted at an etch temperature that is less than 125 degrees Celsius. The etch temperature can be for example a temperature maintained in the processing volume (in which the substrate is disposed), and/or a temperature maintained for a substrate support (e.g., a pedestal, ring, or susceptor) on which the substrate is disposed. In one or more embodiments, the etch temperature is within a range of 35 degrees Celsius to 105 degrees Celsius, such as 40 degrees Celsius to 100 degrees Celsius. In one or more embodiments, the etch temperature is within a range of 40 degrees Celsius to 70 degrees Celsius, such as 45 degrees Celsius to 65 degrees Celsius.

Optional operation 211 of the method 200 includes conducting a spreading resistance profiling (SRP) process on the multi-layer structure. The SRP process can use an SRP material that can include, for example, hydrogen fluoride (HF), ammonia (NH₃), chlorine gas (Cl₂), nitrogen trifluoride (NF₃), chlorine trifluoride (ClF₃), and/or hydrogen chloride (HCl). The SRP process is conducted at an SRP pressure. In one or more embodiments, the SRP pressure is less than 3.0 Torr, such as 2.75 Torr or less. In one or more embodiments, the SRP pressure is 2.0 Torr or less, such as 1.75 Torr or less. In one or more embodiments, the SRP pressure is 1.0 Torr or less, such as 0.75 Torr or less.

In one or more embodiments, after completing operations 201-211 of the method 200, additional processes can be conducted. For example, the method can include further exposing the device containing the multi-layer structure disposed on the substrate to one or more annealing processes. The annealing processes can be or include a furnace anneal process, a spike anneal process, a rapid thermal anneal process, or any combination thereof

FIG. 3 is a cross-sectional view of a multi-layer structure 300 of a device, according to one or more embodiments. The device can be, for example, a semiconductor device. The multi-layer structure 300 can include an epitaxial stack.

The multi-layer structure 300 is formed on a silicon-containing film 302, and the silicon containing film 302 is formed on a substrate 301. The silicon-containing film 302 includes a silicon seed layer 303 and a silicon bulk layer 304. The multi-layer structure 300 includes a plurality of doped silicon-germanium (SiGe) layers 305 and a plurality of silicon layers 306 disposed in an alternating arrangement. For example, each respective silicon layer 306 can be disposed between a first SiGe layer 305a and a second SiGe layer 305b.

The doped SiGe layers 305 respectively include a concentration of a dopant in a range from about 0.01 atomic percent (at%) to about 5 at%. The dopant includes carbon, boron, or a combination of carbon and boron. In one or more embodiments, the dopant includes carbon. The concentration of the dopant is in a range from about 0.1 at% to about 3 at%, or about 0.5 at% to about 1.5 at%. In one or more embodiments, the concentration of the dopant is 0.4 at% to 0.7 at%, such as 0.5 at% to 0.6 at%.

The doped SiGe layers 305 respectively include a concentration of germanium in a range from about 1 at% to about 50 at%, about 5 at% to about 40 at%, about 10 at% to about 30 at%, about 12 at% to about 25 at%, about 13 at% to about 22 at%, about 13 at% to about 20 at%, about 15 at% to about 25 at%, about 15 at% to about 22 at%, about 15 at% to about 20 at%, or about 15 at% to about 18 at%. In one or more embodiments, the concentration of germanium is in a range of about 10% to about 22%, such as about 10 at% to about 20 at%.

The doped SiGe layers 305 respectively have a thickness T1 in a range from about 10 Å to about 500 Å, about 50 Å to about 250 Å, or about 80 Å to about 120 Å. The silicon layers 306 respectively have a thickness T2 in a range from about 100 Å to about 2,000 Å, about 400 Å to about 1,000 Å, or about 600 Å to about 800 Å. The silicon-containing film 302 has a thickness T3 in a range from about 500 Å to about 6,000 Å, about 1,000 Å to about 3,000 Å, or about 1,800 Å to about 2,200 Å.

The present disclosure contemplates that a doped SiGe layer 305 and an adjacent silicon layer 306 can form a mini-stack, and the deposition can be repeated to form a plurality of mini-stacks. In one or more embodiments, the mini-stacks (including a pair of a doped SiGe layer and silicon layer) include about 10 stacks to about 250 stacks, about 30 stacks to about 150 stacks, about 50 stacks to about 120 stacks, about 60 stacks to about 100 stacks, or about 70 stacks to about 90 stacks. The substrate 301 may include silicon, a silicon germanium compound, or a dopant thereof. Other materials are contemplated for the substrate 301.

In one or more embodiments, the device, the doped SiGe layers, the silicon layers, or any portions thereof may be, include, and/or used in a memory device, a DRAM device, a 2D-DRAM device, a 3D-DRAM device, and/or any other microelectronic device or material.

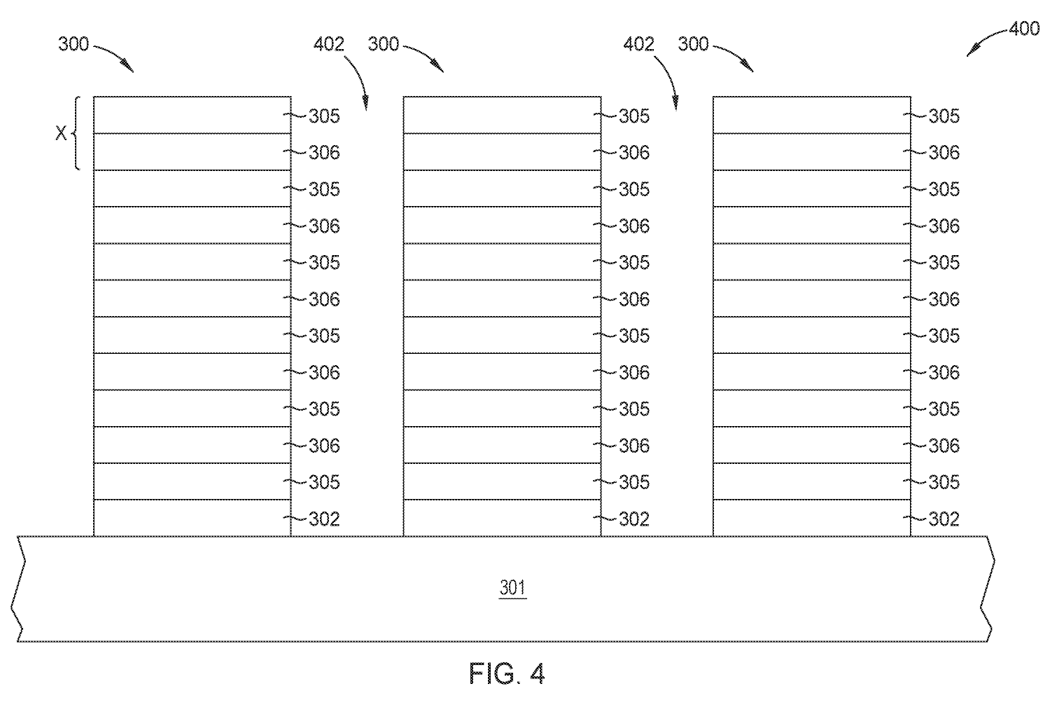

FIG. 4 is a cross-sectional view of a device 400, according to one or more embodiments. The device 400 includes a plurality of the multi-layer structures 300. Trenches 402 are formed between the multi-layer structures 300.

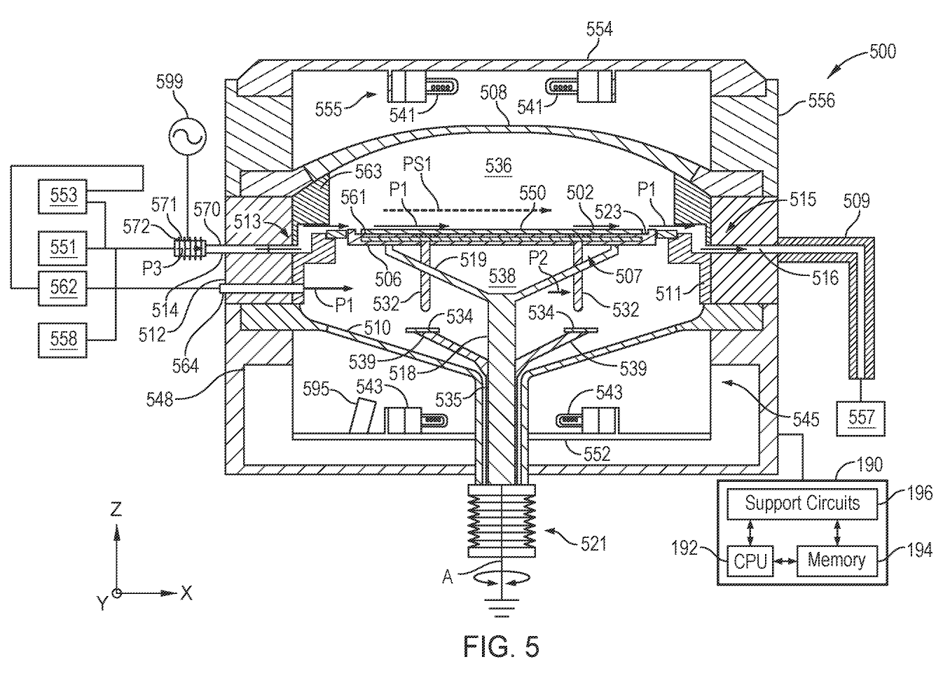

FIG. 5 is a schematic side cross-sectional view of a processing chamber 500, according to one or more embodiments. The processing chamber 500 is a deposition chamber, such as an epitaxial deposition chamber to grow an epitaxial film on a substrate 502. The processing chamber 500 can be used to supply a plasma for plasma operations (such as plasma-assisted film deposition, supply of ions into the substrate 502, pre-cleaning and/or post-cleaning of the substrate 502, etching of the substrate 502, and/or cleaning of the processing chamber 500). In one or more embodiments, the processing chamber 500 creates a cross-flow of precursors across a top surface 550 of the substrate 502. The processing chamber 500 is shown in a processing condition in FIG. 5.

The processing chamber 500 can be used to conducted one or more operations of the method 200. For example, the processing chamber 500 can conduct the deposition of the layers, the etching, and/or the SRP process. The processing chamber 500 is described as generating plasma in a remote plasma source (RPS) manner. The processing chamber 500 can generate plasma in another manner, such as a capacitively coupled plasma (CCP) manner

The processing chamber 500 includes an upper body 556, a lower body 548 disposed below the upper body 556, and a flow module 512 disposed between the upper body 556 and the lower body 548. The upper body 556, the flow module 512, and the lower body 548 form a chamber body. Disposed within the chamber body is a substrate support 506, a plate 508, one or more heat sources 541, 543, and a window 510 (e.g., a lower window, for example a lower dome). The window 510 is formed of an energy transmissive material, such as transparent quartz. In one or more embodiments, the plate 508 is a window, such as an upper window, for example an upper dome. In such an embodiment, the plate 508 can be formed of an energy transmissive material, such as transparent quartz. The one or more heat sources 541, 543 include a plurality of lower heat sources 543 operable to heat a processing volume 536 from one side of the substrate 502 (e.g., from below the substrate 502). In one or more embodiments, the one or more heat sources 541, 543 include a plurality of upper heat sources 541 operable to heat the processing volume 536 from a second side of the substrate 502 (e.g., from above the substrate 502). The chamber body and the plate 508 at least partially define the processing volume 536. In one or more embodiments, the heat sources 541, 543 include lamps (such as halogen lamps or UV lamps). The present disclosure contemplates that other heat sources may be used (in addition to or in place of the lamps) for the various heat sources described herein. For example, resistive heaters, microwave powered heaters, light emitting diodes (LEDs), lasers (e.g., laser diodes), and/or or any other suitable heat source singly or in combination may be used for the various heat sources described herein.

The substrate support 506 is disposed in the processing volume 536 and between the plate 508 and the window 510. The substrate support 506 is disposed between the one or more heat sources 541, 543, and the substrate support 506 supports the substrate 502. The plate 508 is disposed between the substrate support 506 and a lid 554 of the processing chamber 500. In one or more embodiments, the substrate support 506 includes a susceptor. Other substrate supports (including, for example, a substrate carrier, a pedestal, and/or one or more ring segment(s)) are contemplated by the present disclosure. The upper heat sources are disposed between the lid 554 and the plate 508. The plurality of lower heat sources 543 are disposed between the window 510 and a floor 552. The plurality of lower heat sources 543 form a portion of a lower heat source module 545.

The processing volume 536 and a purge volume 538 are between the plate 508 and the window 510. The processing volume 536 and the purge volume 538 are part of an internal volume of the processing chamber 500. One or more liners 511, 563 are disposed inwardly of the chamber body.

The substrate support 506 includes a top surface on which the substrate 502 is disposed. The substrate support 506 is coupled to a shaft 518. In one or more embodiments, the substrate support 506 is coupled to the shaft 518 through one or more arms 519 coupled to the shaft 518. The shaft 518 is coupled to a motion assembly 521. The motion assembly 521 includes one or more actuators and/or adjustment devices that provide movement and/or adjustment for the shaft 518 and/or the substrate support 506 within the processing volume 536.

The substrate support 506 may include lift pin holes 507 disposed therein. The lift pin holes 507 are each sized to accommodate a lift pin 532 for lifting of the substrate 502 from the substrate support 506 before or after a deposition process is performed. The lift pins 532 may rest on lift pin stops 534 when the substrate support 506 is lowered from a process position to a transfer position. The lift pin stops 534 can include a plurality of arms 539 that attach to a shaft 535.

The flow module 512 includes one or more gas inlets 514 (e.g., a plurality of gas inlets), one or more purge gas inlets 564 (e.g., a plurality of purge gas inlets), and one or more gas exhaust outlets 516. The one or more gas inlets 514 are part of an inject portion 513 of the chamber body, and the one or more gas exhaust outlets 516 are part of an exhaust portion 515 of the chamber body. A pre-heat ring 517 is disposed below the one or more gas inlets 514 and the one or more gas exhaust outlets 516. The gas inlet(s) 514 and the purge gas inlet(s) 564 are each positioned to flow a respective one or more process gases P1 and one or more purge gases P2 parallel to the top surface 550 of a substrate 502 disposed within the processing volume 536. The gas inlet(s) 514 are fluidly connected to one or more process gas sources 551 and one or more etch gas sources 553. The purge gas inlet(s) 564 are fluidly connected to one or more purge gas sources 562. The one or more gas exhaust outlets 516 are fluidly connected to an exhaust pump 557. The one or more process gases P1 supplied using the one or more process gas sources 551 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 562 can include one or more inert gases (such as one or more of argon (Ar), helium (He), and/or nitrogen (N₂)). One or more etch gases supplied using the one or more etch gas sources 553 can include one or more of hydrogen (H) and/or chlorine (Cl). In one or more embodiments, the one or more process gases P1 include silicon phosphide (SiP) and/or phosphine (PH₃), and the one or more cleaning gases include hydrochloric acid (HCl).

One or more plasma gas sources 558 are also fluidly connected to the gas inlet(s) 514. The one or more plasma gas sources 558 supply one or more plasma precursor gases that can be ignited into a plasma. A flow housing 571 is disposed at least partially outward of the flow module 512 and is fluidly connected to the flow module 512 through one or more flow channels 570 disposed between the flow housing 571 and the gas inlet 514. One or more radio frequency (RF) coils 572 is disposed at least partially around the flow housing 571. For example, the one or more RF coils 572 can be wound around the flow housing 571. As a plasma gas P3 flows from the plasma gas source 558 and through the flow housing 571, the one or more RF coils ignite the plasma gas P3 into a plasma PS1 which then flows through the one or more flow channels 570 and into the gas inlet 514. The one or more flow channels 570 can be formed, for example, in one or more gas boxes. RF current flows through the one or more RF coils while the gas P3 flows, which applies a voltage across the gas P3 to ignite the gas P3 into the plasma PS1. The one or more gas exhaust outlets 516 are further connected to or include an exhaust system 509. The exhaust system 509 fluidly connects the one or more gas exhaust outlets 516 and the exhaust pump 557.

The processing chamber 500 includes the one or more liners 511, 563 (e.g., a lower liner 511 and an upper liner 563). The flow module 512 (which can be at least part of a sidewall of the processing chamber 500) includes the one or more gas inlets 514 in fluid communication with the processing volume 536. The one or more gas inlets 514 are in fluid communication with one or more flow gaps between the upper liner 563 and a lower liner 511.

The present disclosure contemplates that the plasma PS1 and the one or more process gases P1 can flow simultaneously and/or sequentially with respect to each other. In one or more embodiments during the cleaning operation the plasma gas P3 is flowed through the flow housing 571 simultaneously with the process gases P1 (the plasma gas P3 can be flowed with the process gases P1 or separately from the process gases P1), or before or after the flowing of the one or more process gases P1. The plasma PS1 may flow into the processing volume 536 before the processing gas P1 to pre clean the substrate 502. The plasma may flow into the processing volume 536 after the process gases P1 in order to clean the processing volume 536 after deposition operations. In one or more embodiments, the plasma gas P3 flows simultaneously with the process gases P1 through the flow housing 571. The plasma PS1 and the process gases P1 may flow into the processing volume 536 simultaneously where the plasma PS1 may assist in the deposition operation by facilitating activation of the process gas(es) P1 (e.g., by breaking bonds of the process gas(es) P1. The present disclosure contemplates that a voltage and/or a frequency of RF power 599 applied to the one or more RF coils 572 can be varied and/or pulsed. The frequency can involve a single frequency or multiple frequencies. The multiple frequencies can be combined.

During deposition, in one or more embodiments, the substrate 502 is heated to a target temperature of within a range of 150 degrees Celsius to 1,000 degrees Celsius, such as 500 degrees Celsius to 800 degrees Celsius. In one or more embodiments, the target temperature for the substrate 502 is within a range of 380 degrees Celsius to 600 degrees Celsius. In one or more embodiments, the target temperature for the substrate 502 is less than 500 degrees Celsius.

Benefits of the present disclosure include uniformities of semiconductor stacks, such as stacks that include SiGe layers and silicon layers. As an example, aspects of the method 200 facilitate resistivity uniformity across a depth of the stacks. As another example, aspects of the method 200 facilitate structural uniformity (such as facial uniformity) across a depth of the stacks. Such benefits are facilitated for stacks and trenches that have a high aspect ratio (e.g., a relatively high height versus width).

While the foregoing is directed to embodiments of the disclosure, other and further embodiments may be devised without departing from the basic scope thereof, and the scope thereof is determined by the claims that follow. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated. As used herein, the term “about” refers to a +/-10% variation from the nominal value. It is to be understood that such a variation can be included in any value provided herein.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. A device, comprising:
a multi-layer structure disposed on a substrate, the multi-layer structure comprising:
a plurality of doped silicon-germanium (SiGe) layers, the doped SiGe layers respectively comprising a dopant having a concentration in a range from about 0.01 atomic percent (at%) to about 5 at%; and
a plurality of silicon layers disposed in an alternating arrangement with the doped SiGe layers such that a respective silicon layer is disposed between a respective first doped SiGe layer and a respective second doped SiGe layer.

2. The device of claim 1, wherein the dopant comprises carbon, boron, or a combination of carbon and boron.

3. The device of claim 1, wherein the dopant comprises carbon.

4. The device of claim 1, wherein the concentration of the dopant is in a range from about 0.1 at% to about 3 at%.

5. The device of claim 4, wherein the concentration of the dopant is in a range from about 0.5 at% to about 1.5 at%.

6. The device of claim 1, wherein each of the first and second doped SiGe layers respectively has a thickness in a range from about 10 Å to about 500 Å.

7. The device of claim 6, wherein each of the first and second doped SiGe layers respectively has a thickness in a range from about 80 Å to about 120 Å.

8. The device of claim 1, wherein the respective silicon layer has a thickness in a range from about 600 Å to about 800 Å.

9. The device of claim 1, further comprising a silicon-containing film disposed between the substrate and the multi-layer structure, wherein the silicon-containing film has a thickness in a range from about 1,800 Å to about 2,200 Å.

10. A method of processing a substrate, comprising:
flowing a first gas and a dopant precursor to form a doped SiGe layer, the doped SiGe layer comprising a dopant in a range from about 0.1 at% to about 3 at%;
ceasing the flow of the dopant precursor; and
flowing a second gas to form a silicon layer on the doped SiGe layer, the silicon layer and the doped SiGe layer forming at least part of a multi-layer structure.

11. The method of claim 10, wherein the doped SiGe layer has a concentration of germanium in a range of 10 at% to 22 at%.

12. The method of claim 10, wherein the first gas includes a silicon precursor and a germanium precursor, and the dopant precursor includes a silicon-carbon precursor.

13. The method of claim 12, wherein the flowing of the second gas includes continuing to flow the silicon precursor and ceasing the flow of the germanium precursor.

14. The method of claim 10, further comprising etching the multi-layer structure using an etch temperature that is less than 125 degrees Celsius.

15. The method of claim 14, wherein the etch temperature is within a range of 40 degrees Celsius to 70 degrees Celsius.

16. The method of claim 10, further comprising conducting a spreading resistance profiling (SRP) process on the multi-layer structure using an SRP pressure that is less than 3.0 Torr.

17. The method of claim 16, wherein the SRP pressure is 1.0 Torr or less.

18. A non-transitory computer readable medium comprising instructions that when executed cause a plurality of operations to be conducted, the plurality of operations comprising:
flowing a first gas and a dopant precursor to form a doped SiGe layer;
flowing a second gas to form a silicon layer on the doped SiGe layer; and
flowing an etch gas using an etch temperature that is within a range of 35 degrees Celsius to 105 degrees Celsius.

19. The non-transitory computer readable medium of claim 18, wherein the etch temperature is within a range of 40 degrees Celsius to 70 degrees Celsius.

20. The non-transitory computer readable medium of claim 18, wherein the plurality of operations further comprise conducting a spreading resistance profiling (SRP) process using an SRP pressure that is less than 3.0 Torr.
